(19) United States
(12) Patent Application Publication
(10) Pub. No.: US 2012/0227803 A1
(43) Pub. Date: Sep. 13, 2012

(54) COMPOUND THIN FILM SOLAR CELL

(75) Inventors: Naoyuki Nakagawa, Tokyo (JP); Yasuyuki Hotta, Tokyo (JP); Shinya Sakurada, Tokyo (JP); Yasutaka Nishida, Tokyo (JP); Satoshi Itoh, Ibaraki (JP)

(73) Assignee: KABUSHIKI KAISHA TOSHIBA, Tokyo (JP)

(21) Appl. No.: 13/420,836

(22) Filed: Mar. 15, 2012

Related U.S. Application Data
(63) Continuation-in-part of application No. PCT/JP2009/004842, filed on Sep. 25, 2009.

(51) Int. Cl. H01L 31/0232

(52) U.S. Cl. 136/256

(57) ABSTRACT

A compound thin film solar cell contains at least: includes a substrate; a back surface electrode provided on the substrate; an extraction electrode provided on the back surface electrode; a light absorbing layer provided on the back surface electrode; a buffer layer provided on the light absorbing layer; a transparent electrode layer provided on the buffer layer; an anti-reflective film provided on the transparent electrode layer; and an extraction electrode provided on the transparent electrode layer, wherein the light absorbing layer is formed from Cu(Al_{1-x-y}GaₓIn_{y})(Te_{1-z}O_{z})₂ [provided that x and y are in the ranges defined by (Expression 1), with z=0; or x and y are in the ranges defined by (Expression 2), with 0.001≦z≦0.0625)], and the compound has a chalcopyrite type crystal structure.

Eg=2.25−1.02x−1.29y (1.5≧Eg≧1.0) (Expression 1)

Eg=2.25−1.02x−1.29y (2.25≧Eg≧1.0) (Expression 2)

### CROSS-REFERENCE TO RELATED APPLICATION

This application is a continuation-in-part (CIP) application based upon the International Application PCT/JP2009/004842, the International Filing Date of which is Sep. 25, 2009, the entire content of which is incorporated herein by reference.

### FIELD

The present invention relates to a compound thin film solar cell.

### BACKGROUND

Among compound semiconductors that are used in the light-absorbing layer of solar cells, the II-VI system represented by CdTe and the I-III-VI₂ system represented by CuInSe₂ are widely known. The I-III-VI₂ system compound semiconductors having a chalcopyrite structure are composed mainly of copper (Cu) as the Group I element, indium (In) and/or gallium (Ga) as the Group III element, and selenium (Se) and/or sulfur (S) as the Group VI element. As there are a diverse variety of relevant materials available, the band gap can be easily controlled by appropriately selecting the materials. In fact, attempts have been taken to adjust the band gap to 1.4 eV, which is the optimum value for the absorption of sunlight, by forming a solid solution of CuInSe₂ (Eg=1.04 eV) and CuGaSe₂ which have large band gaps (Eg=1.68 eV).

A compound thin film solar cell which uses Cu(In₁₋ₓGaₓ)(Se_{1-y}S_{y})₂ in the light absorbing layer, contains In and Ga as constituent elements. Since In and Ga are rare metals, there is a high possibility that a stable supply of the metals may not be achieved easily because resource reserves are small, or because it is difficult to produce high quality ores that can be mined with high economic efficiency. Furthermore, because high-level technologies or large amounts of energy are required for the refining of the metals, the processes of refining the metals from their ores are not simple, which serves as a causative factor for price increases.

Highly efficient CIGS (Cu(In₁₋ₓGaₓ)Se₂) solar cells are obtained by using thin films of p-type semiconductors in which CIGS has a composition that is in a slight excess of the Group III element as compared with the stoichiometric ratio. The production can be carried out by using a multiple deposition method, particularly a three-stage method. In the three-stage method, In, Ga, and Se are deposited in the first layer to form an (In,Ga)₂Se₃ film, and then Cu and Se only are supplied so as to convert the overall composition of the film into a Cu-excess composition. Finally, In, Ga and Se fluxes are supplied again, and thus the final composition of the film is converted into an (In,Ga)-excess composition. Deposition methods enable precise controlling of the chemical composition, and this are capable of the production of highly efficient CIGS solar cells. However, it is difficult to produce solar cells with large surface areas, owing to the restrictions in process.

### SUMMARY OF THE INVENTION

A compound thin film solar cell of an embodiment contains at least: includes a substrate; a back surface electrode provided on the substrate; an extraction electrode provided on the back surface electrode; a light absorbing layer provided on the back surface electrode; a buffer layer provided on the light absorbing layer; a transparent electrode layer provided on the buffer layer; an anti-reflective film provided on the transparent electrode layer; and an extraction electrode provided on the transparent electrode layer, wherein the light absorbing layer is formed from Cu(Al_{1-x-y}GaₓIn_{y})(Te_{1-z}O_{z})₂ [provided that x and y are in the ranges defined by (Expression 1), with z=0; or x and y are in the ranges defined by (Expression 2), with 0.001≦z≦0.0625)], and the compound has a chalcopyrite type crystal structure:

Eg=2.25−1.02x−1.29y (1.5≧Eg≧1.0), (Expression 1)

and

Eg=2.25−1.02x−1.29y (2.25≧Eg≧1.0). (Expression 2)

### BRIEF DESCRIPTION OF THE DRAWINGS

FIG. 1 is a diagram of a unit cell of CuAl(Te_{1-z}O_{z})₂ (z=0.03125);

FIG. 2A is a diagram illustrating the density of states of CuAl (Te_{1-z}O_{z})₂ (z=0.03125);

FIG. 2B is a diagram illustrating the band diagram of CuAl (Te_{1-z}O_{z})₂ (z=0.03125);

FIG. 3 is a conceptual diagram of the basic structure of the compound thin film solar cell of the present invention;

FIG. 4 is a band diagram for the interface between the light absorbing layer and the buffer layer;

FIG. 5 is a diagram illustrating the results of X-ray diffraction of a CuAlTe₂ thin film; and

FIG. 6 is a diagram illustrating the results for an evaluation of the optical absorption characteristics of a CuAlTe₂ thin film.

### DETAILED DESCRIPTION

A compound thin film solar cell of an embodiment comprising at least: a substrate; a back surface electrode provided on the substrate; an extraction electrode provided on the back surface electrode; a light absorbing layer provided on the back surface electrode; a buffer layer provided on the light absorbing layer; a transparent electrode layer provided on the buffer layer; an anti-reflective film provided on the transparent electrode layer; and an extraction electrode provided on the transparent electrode layer, wherein the light absorbing layer is formed from Cu(Al_{1-x-y}GaₓIn_{y})(Te_{1-z}O_{z})₂ [provided that x and y are in the ranges defined by (Expression 1), with z=0; or x and y are in the ranges defined by (Expression 2), with 0.001≦z≦0.0625)], and the compound has a chalcopyrite type crystal structure:

Eg=2.25−1.02x−1.29y (1.5≧Eg≧1.0), (Expression 1)

and

Eg=2.25−1.02x−1.29y (2.25≧Eg≧1.0). (Expression 2)

Hereinafter, embodiments of the present invention will be described in detail with reference to the attached tables and diagrams.

In the chalcopyrite type compound semiconductors of the I-III-VI₂ system, Se has been conventionally used as the Group VI element. However, since Se is highly toxic and broadens the band gap, there are environmental problems and cost problems, such as that it is necessary to use more of Ga or In, which are rare metals.

Tellurium (Te) has such good characteristics that it is less toxic than Se, and it has a smaller band gap as compared with those of chalcopyrite type compound semiconductors using Se as the Group VI element, and thus it reduces the use of rare elements.

CuAlTe₂, CuGaTe₂ and CuInTe₂ all exhibit a chalcopyrite structure, and form solid solutions.

Table 1 illustrates the band gaps of chalcopyrite type compound semiconductors of the I-III-VI₂ system which contain Te as the Group VI element. The value of CuAlTe₂ shown in Table 1 is an experimental value found by the inventors, and the values of CuGaTe₂ and CuInTe₂ are experimental values found in the literature. As is obvious from Table 1, the band gap can be largely modulated by changing only the Group III element in the I-III-VI₂ system.

A preferred band gap of the solar radiation spectrum is from 1.0 eV to 1.5 eV. The optimum band gap of the solar radiation spectrum is often considered to be from 1.4 eV to 1.5 eV. It has also been reported that the maximum conversion efficiency is obtained near 1.2 eV.

TABLE 1

| Chemical Formula | band gap (eV) |
|---|---|
| CuAlTe₂ | 2.25 |
| CuGaTe₂ | 1.23 |
| CuInTe₂ | 0.96 |

In these solid solutions, the band gap can be arbitrarily modulated between 0.96 eV of CuInTe₂ having the smallest band gap value and 2.25 eV of CuAlTe₂ having the largest band gap value. Some examples of the band gap values obtainable when a portion of Al of CuAlTe₂ is substituted with Ga or In, are presented in Table 2. The values indicated in the table are expressed in the molar ratios in the solid solutions.

TABLE 2

| Value of 1 − x − y in | Value of x in | Value of y in | |
|---|---|---|---|
| Cu(Al_{1-x-y}GaₓIn_{y})Te₂ | Cu(Al_{1-x-y}GaₓIn_{y})Te₂ | Cu(Al_{1-x-y}GaₓIn_{y})Te₂ | |
| (mol) | (mol) | (mol) | Eg (eV) |
| 0.167 | 0 | 0.969 | 1.0 |
| 0.265 | 0 | 0.814 | 1.2 |
| 0.031 | 0 | 0.659 | 1.4 |
| 0.186 | 0 | 0.581 | 1.5 |
| 0.351 | 0.833 | 0 | 1.4 |
| 0.419 | 0.735 | 0 | 1.5 |

In the case of (Cu(Al₁₋ₓGaₓ)Te₂) where a portion of Al of CuAlTe₂ has been substituted with Ga, in order to modulate the band gap to the range of from 1.0 eV to 1.5 eV, which is a preferred band gap for the light absorbing layer of a solar cell, it is desirable to produce a solid solution having a composition which satisfies the requirements of 0.73≦x≦1.0.

In the case of (Cu(Al_{1-y}In_{y})Te₂) where a portion of Al of CuAlTe₂ has been substituted with In, in order to modulate the band gap to the range of from 1.0 eV to 1.5 eV, which is a preferred band gap for the light absorbing layer of a solar cell, it is desirable to produce a solid solution having a composition which satisfies the requirements of 0.58≦y≦0.97.

It is also possible to substitute Al with both the elements of In and GaₓIn that case, it is desirable that the range of composition satisfy the formula: Cu(Al_{1-x-y}GaₓIn_{y})Te₂ (provided that x and y are such that Eg=2.25-1.02x−1.29y (1≧x+y>0, and 1.5≧Eg≧1.0)).

A compound semiconductor obtained by partially substituting a portion of Te of Group VI of a chalcopyrite type compound semiconductor of the I-III-VI₂ system, which is used as the light absorbing layer, with Se or S (the molar amount of Se or S is smaller than the molar amount of Te), can also be used as the light absorbing layer. In that case, it is desirable that the band gap be in the range of from 1.0 eV to 1.5 eV, and that the compound semiconductor maintain the chalcopyrite structure.

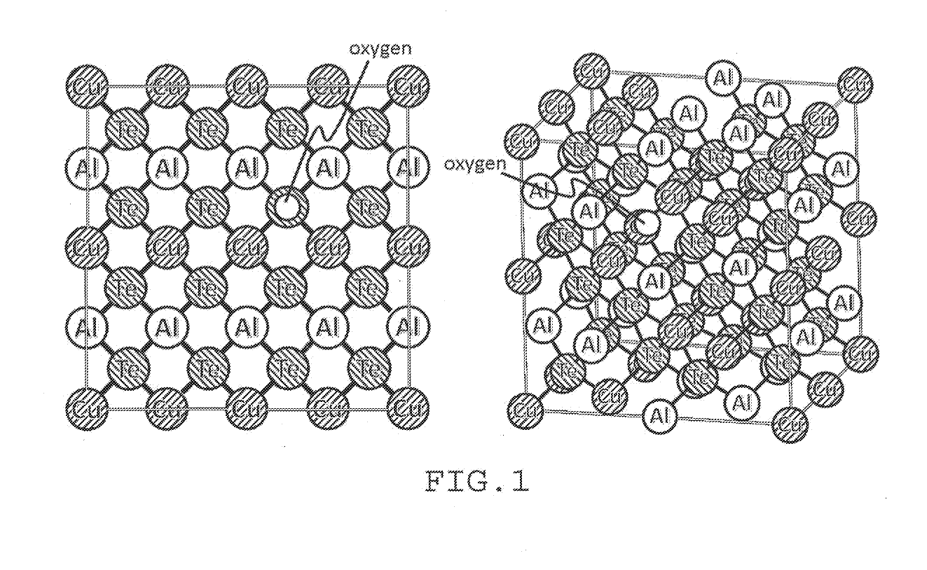

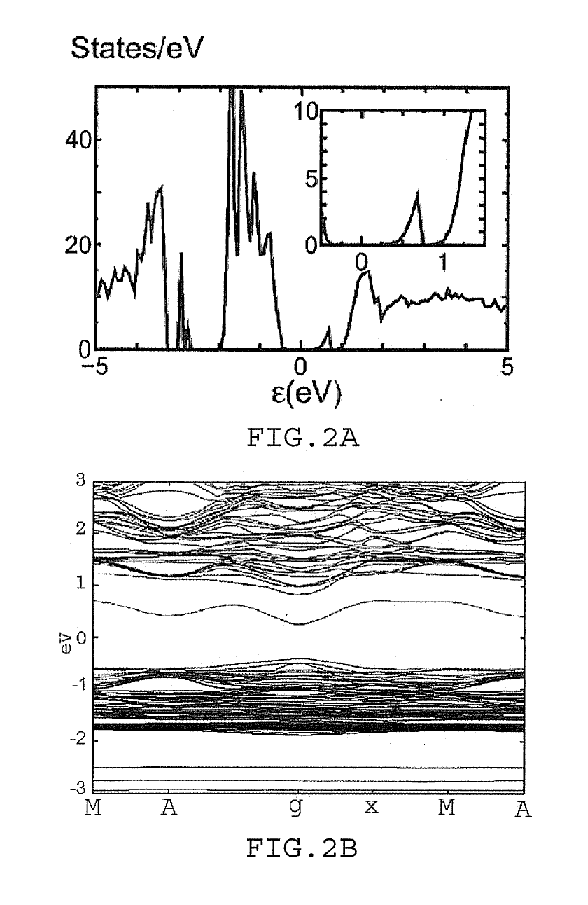

In order to further increase the efficiency, an investigation was conducted to introduce an intermediate level of a chalcopyrite type compound semiconductor (Cu(Al_{1-x-y}GaₓIn_{y})Te₂. As a result of conducting extensive investigations, the inventors found that when a portion of Te of Group VI is substituted with oxygen (Cu(Al_{1-x-y}GaₓIn_{y})(Te_{1-z}O_{z})₂), an appropriate intermediate level of the band gap is formed. In regard to the oxygen substitution, specific investigations were conducted according to the first-principle calculation. FIG. 1 presents the crystal structure of a chalcopyrite type compound semiconductor, CuAlTe₂, in which Te has been partially substituted with O. The lattice constants of the unit cell of CuAlTe₂ were such that a=5.964 Å and c=11.78 Å, and that, as the band gap of the compound semiconductor, the band gap value of a bulk single crystal, 2.06 eV was used. The results of the calculation for the system in which one of thirty-two Te atoms in the total number of atoms of a unit cell, which is 64 atoms, has been substituted with oxygen, i.e., CuAl(Te_{1-z}O_{z})₂ (z=0.03125), are presented in FIG. 2A and FIG. 2B. The formation of a conspicuous intermediate level in the gap as a result of oxygen substitution was confirmed from the density of states and the band structure. As can be seen from the calculation results, when the amount of oxygen substitution, z, of CuAl(Te_{1-z}O_{z})₂ is from 0.001 to 0.0625, an intermediate level is formed, and high conversion efficiency is desired. As the amount of oxygen substitution is smaller, the density of states becomes steeper.

The optical band gap of a CuAlTe₂ thin film is 2.25 eV, and when Al is substituted with In or Ga, the band gap can be controlled down to 1.0 eV. For any parent phase having a band gap of various values, when an intermediate level is formed, even light from a longer wavelength region can be captured, and a further enhancement of the efficiency of solar cells is anticipated.

Since Te has a lower vapor pressure than Se, it is expected that handling of Te should be easy, and it should be easy to control the composition when film formation is carried out. Furthermore, when a Te-based chalcopyrite type compound semiconductor is used in the parent phase, the addition amount of In or Ga for adjusting the band gap to the optimum value can be decreased, and thereby segregation can be suppressed. Thus, a thin film having a uniform composition can be produced.

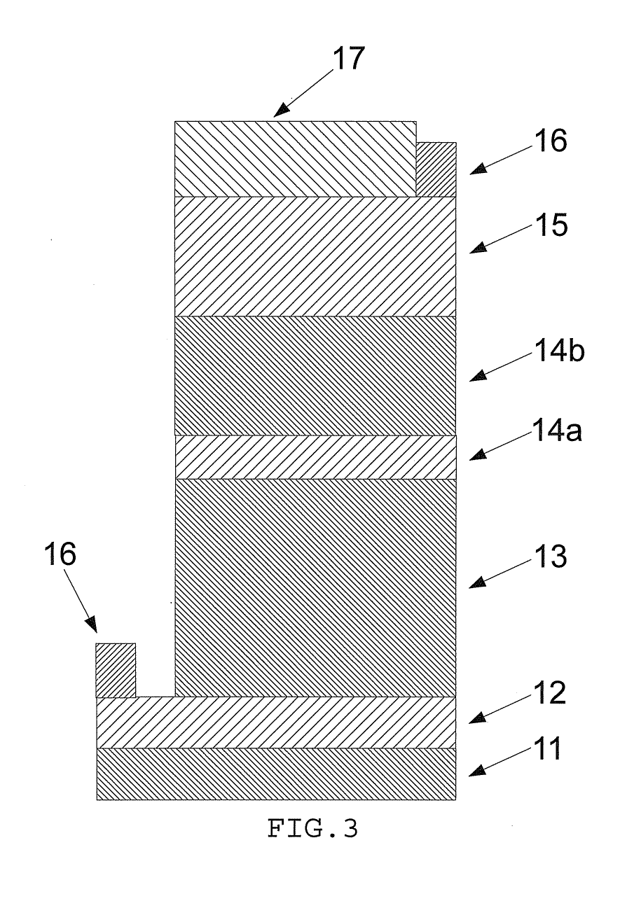

FIG. 3 illustrates a schematic cross-sectional diagram of a compound thin film solar cell according to an embodiment of the present invention. The compound thin film solar cell is composed of a substrate 11, a back surface electrode 12, a light absorbing layer 13, buffer layers 14a and 14b, a transparent electrode layer 15, an extraction electrode 16, and an anti-reflective film 17.

As the substrate 11, it is desirable to use soda-lime glass, and a substrate of a metal such as stainless steel, Ti or Cr, or a resin such as polyimide can also be used.

As the back surface electrode, a metal film of tungsten (W) or the like can be used. Among others, it is desirable to use a molybdenum (Mo) film.

As the buffer layer 14, CdS, Zn(O, S, OH), or ZnO with added Mg can be used. FIG. 4 illustrates the band structure of the p-n junction interface in a compound thin film solar cell. It is believed that the chalcopyrite type compound semiconductor of the light absorbing layer 13 functions as a p-type semiconductor; the buffer layer 14a represented by CdS or ZnO:Mg as an n-type semiconductor; and the buffer layer 14b represented by ZnO as an n type layer. Recombination of carriers can be reduced by selecting the material of the buffer layer 14a to bring about a conduction band offset (CEO), ΔE_{c}, at the p-n junction interface. The conduction band offset (CBO), ΔE_{c}, is desirably equal to or greater than 0 eV and equal to or less than 0.4 eV, and more desirably equal to or greater than 0.1 eV and equal to or less than 0.35 eV. The conduction band structure or the conduction band offset can be directly evaluated by inverse photoemission spectroscopy, which is a reverse process of photoelectron emission. In a practical solar cell structure, the thicknesses of the window layer and the buffer layer that are formed on the light absorbing layer are respectively as large as several micrometers (μm) to several ten nanometers (nm). Therefore, in order to perform an evaluation of an interface that is located at a position deep from the surface, it is necessary to remove the various layers without damage or deterioration, and usually etching by means of a low-energy ion beam is used.

The transparent electrode layer 15 needs to transmit solar radiation and to have electrical conductivity, and for example, ZnO:Al containing 2 wt % of alumina (Al₂O₃), or ZnO:B containing B from diborane as a dopant, can be used to form the transparent electrode layer.

As the extraction electrode 16, for example, Al, Ag or Au can be used. Furthermore, in order to increase the adhesiveness to the transparent electrode 15, Ni or Cr is first deposited, and then Al, Ag or Au may be deposited.

As the anti-reflective film 17, it is desirable to use, for example, MgF₂.

Hereinafter, the present invention will be described by way of Examples.

### Example 1

A soda-lime glass substrate was used as the substrate 11, and a molybdenum (Mo) thin film which would serve as the back surface electrode 12 was deposited thereon by a sputtering method to a thickness of about 700 nm. Sputtering was carried out by using Mo as the target, and applying a radio frequency (RF) power of 200 W in an argon (Ar) gas atmosphere.

After the deposition of the Mo thin film which would serve as the back surface electrode 12, a Cu(Al_{1-y}In_{y})Te₂ thin film which would serve as the light absorbing layer 13 was deposited in the same manner by RF sputtering to a thickness of about 2 μm. Here, y in the feed composition of the target was adjusted to 0.8, so that a band gap value of about 1.18 eV would be obtained. Film formation was carried out by applying an RF power of 200 W in an Ar gas atmosphere.

After the film formation, the film-forming chamber was subjected to a vacuum, and a heating treatment was carried out at 500° C. in an ultra-high vacuum atmosphere. The Cu(Al_{1-y}In_{y})Te₂ thin film obtained immediately after the sputtering film formation process was amorphous and had a very small particle size. However, once the thin film was heat treated at a high temperature, the thin film underwent crystallization, and the particle size also increased to 100 nm or greater. Thus, the thin film can contribute to an increase in the efficiency of solar cells.

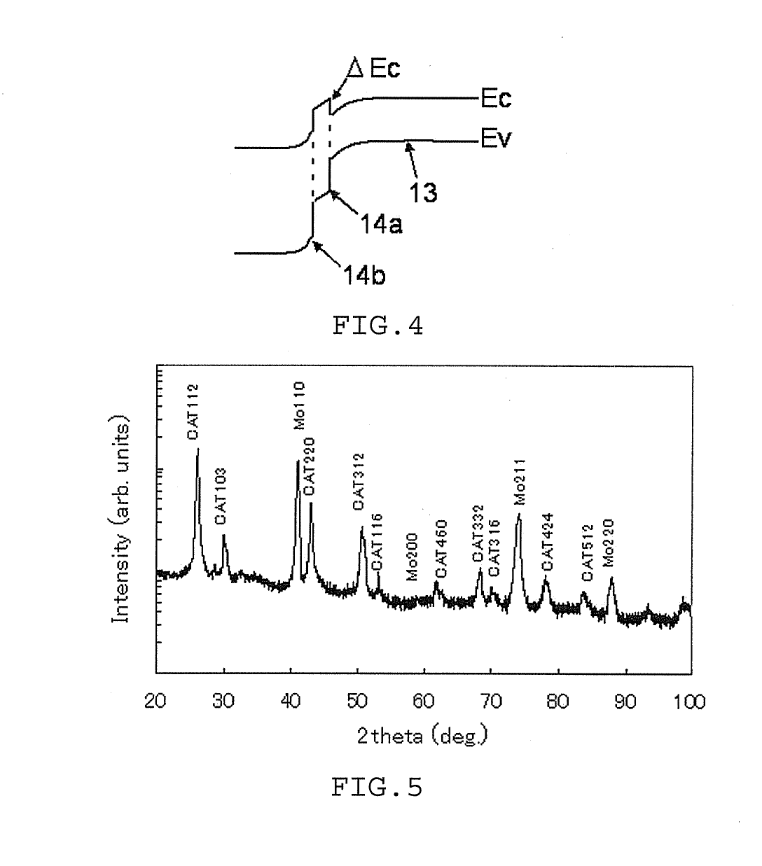

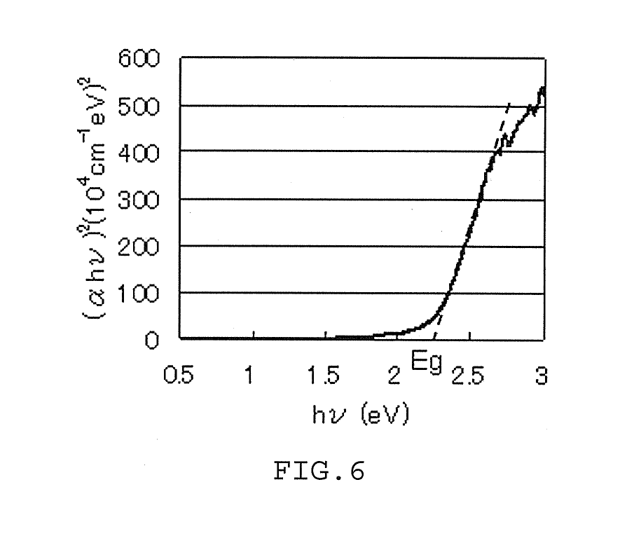

FIG. 5 illustrates the results of X-ray diffraction of a thin film obtained by depositing CuAlTe₂ as the parent phase under the same conditions as the film forming conditions described above. It is known that the thin film which was produced under the film forming conditions described above and would serve as the light absorbing layer 13, forms a single-phase film having a chalcopyrite type structure. From an evaluation of the optical absorption characteristics of the CuAlTe₂ thin film thus produced, the optical band gap was estimated to be 2.25 eV (FIG. 6).

On the light absorbing layer 13 thus obtained, a Mg-added ZnO thin film was deposited as the buffer layer 14a to a thickness of about 50 nm. As shown in FIG. 4, the addition amount of Mg was adjusted to 20% so that a band offset would be formed at the interface between the light absorbing layer 13 and the buffer layer 14a. Film formation was carried out by RF sputtering, but in consideration of plasma damage at the interface, the sputtering process was carried out at an output power of 50 W. Onto this buffer layer 14a, a ZnO thin film was deposited as the buffer layer 14b, and subsequently, ZnO:Al containing 2 wt % of alumina (Al₂O₃) was deposited thereon as the transparent electrode 15 to a thickness of about 1 μm. NiCr and Au were deposited thereon as the extraction electrode 16 by a vapor deposition method. The film thicknesses of NiCr and Au were 100 nm and 300 nm, respectively. Finally, MgF₂ was deposited as the anti-reflective film 17 by a sputtering method to a thickness of about 500 nm. Thereby, the compound thin film solar cell shown in FIG. 3 was produced.

### Example 2

A soda-lime glass substrate was used as the substrate 11, and a Mo thin film which would serve as the back surface electrode 12 was deposited thereon by a sputtering method to a thickness of about 700 nm. Sputtering was carried out by using Mo as the target, and applying an RF power of 200 Win an Ar gas atmosphere.

After the deposition of the Mo thin film which would serve as the back surface electrode 12, a CuAlTe₂ thin film which would serve as the light absorbing layer 13 was deposited in the same manner by RF sputtering to a thickness of about 2 μm. Film formation was carried out by applying an RF power of 200 W in an Ar gas atmosphere.

After the film formation, the film-forming chamber was subjected to a vacuum, and a heating treatment was carried out at 500° C. in an ultra-high vacuum atmosphere. The CuAlTe₂ thin film obtained immediately after the sputtering film formation process was amorphous and had a very small particle size. However, once the thin film was heat treated at a high temperature, the thin film underwent crystallization, and the particle size also increased to 100 nm or greater.

The CuAlTe₂ thin film thus produced was subjected to oxygen ion implantation with 90 keV of energy. Subsequently, in order to compensate for the defects occurred as a result of ion implantation, recrystallization was carried out by excimer laser annealing, and thereby partial substitution of Te with O was achieved.

On the light absorbing layer 13 thus obtained, a Mg-added ZnO thin film was deposited as the buffer layer 14a to a thickness of about 50 nm. The addition amount of Mg was adjusted to 40% so that a band offset would be formed against the CuAlTe₂ having a wide band gap, at the interface between the light absorbing layer 13 and the buffer layer 14a. Film formation was carried out by RF sputtering, but in consideration of plasma damage at the interface, the sputtering process was carried out at an output power of 50 W. Onto this buffer layer 14a, a ZnO thin film was deposited as the buffer layer 14b, and subsequently, ZnO:Al containing 2 wt % of alumina (Al₂O₃) was deposited thereon as the transparent electrode 15 to a thickness of about 1 μm. NiCr and Au were deposited thereon as the extraction electrode 16 by a vapor deposition method. The film thicknesses of NiCr and Au were 100 nm and 300 nm, respectively. Finally, MgF₂ was deposited as the anti-reflective film 17 by a sputtering method to a thickness of about 500 nm. Thereby, the compound thin film solar cell shown in FIG. 3 was produced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A compound thin film solar cell comprising at least:
a substrate;
a back surface electrode provided on the substrate;
an extraction electrode provided on the back surface electrode;
a light absorbing layer provided on the back surface electrode;
a buffer layer provided on the light absorbing layer;
a transparent electrode layer provided on the buffer layer;
an anti-reflective film provided on the transparent electrode layer; and
an extraction electrode provided on the transparent electrode layer,
wherein the light absorbing layer is formed from Cu(Al_{1-x-y}GaₓIn_{y})(Te_{1-z}O_{z})₂ [provided that x and y are in the ranges defined by (Expression 1), with z=0; or x and y are in the ranges defined by (Expression 2), with 0.001≦z≦0.0625)], and the compound has a chalcopyrite type crystal structure:
Eg=2.25−1.02x−1.29y (1.5≧Eg≧1.0), (Expression 1)
and
Eg=2.25−1.02x−1.29y (2.25≧Eg≧1.0). (Expression 2)

2. The solar cell according to claim 1,
wherein a portion of Te in the light absorbing layer is substituted with any one of Se, S, or Se and S, and
the total mole number of substituted Se and S is smaller than the mole number of Te.

3. The solar cell according to claim 1,
wherein the buffer layer is formed from CdS, Zn (O, S, OH), or ZnO:Mg.

4. The solar cell according to claim 1,
wherein the conduction band offset (ΔE_{c}) of the band structure formed at the interface between the light absorbing layer and the buffer layer is such that 0 eV<ΔE_{c}≦0.4 eV.

5. The solar cell according to claim 1,
wherein ZnO, ZnO:Al, or ZnO:B is used in the transparent electrode layer.

6. The solar cell according to claim 1,
wherein the conduction band offset (ΔEₑ) of the band structure formed at the interface between the light absorbing layer and the buffer layer is such that 0.1 eV≦ΔE_{c}≦0.35 eV.

7. The solar cell according to claim 1,
wherein the light absorbing layer is subjected to oxygen ion implantation.

8. The solar cell according to claim 7,
wherein the light absorbing layer is recrystallized after the implantation.

9. The solar cell according to claim 1,
wherein the particle size of the light absorbing layer is 100 nm or greater.

10. The solar cell according to claim 1,
wherein the light absorbing includes solid solutions.
